(19) United States
(12) Patent Application Publication
(10) Pub. No.: US 2024/0258233 A1
(43) Pub. Date: Aug. 1, 2024

(54) STAIRCASE LANDING PADS VIA RIVETS

(71) Applicant: Micron Technology, Inc., Boise, ID (US)

(72) Inventors: Yiping Wang, Boise, ID (US); Harsh Narendrakumar Jain, Boise, ID (US)

(21) Appl. No.: 18/420,538

(22) Filed: Jan. 23, 2024

Related U.S. Application Data
(60) Provisional application No. 63/442,060, filed on Jan. 30, 2023.

(51) Int. Cl. H01L 23/528; H01L 21/28; H01L 21/311; H01L 21/768

(52) U.S. Cl. CPC H01L 23/528; H01L 21/31111; H01L 21/76877; H01L 29/4011

(57) ABSTRACT

Methods, systems, and devices for staircase landing pads via rivets are described. A memory device may include a staircase region with a stack of materials that includes a set of word lines, where the set of word lines progressively decrease in length to form a staircase structure. The staircase region may additionally include a rivet that couples a first word line from the set of word lines with a conductive pillar. Additionally, the conductive pillar may traverse the stack perpendicularly to the set of word lines and may couple the first word line with supporting circuitry. In some cases, a first thickness of the first word line adjacent to the conductive pillar may be greater than a second thickness of other word lines adjacent to the conductive pillar. The staircase region may additionally include an oxide material that isolates the conductive pillar from the other word lines.

### CROSS REFERENCE

The present application for patent claims priority to U.S. Patent Application No. 63/442,060 by Wang et al., entitled “STAIRCASE LANDING PADS VIA RIVETS,” filed Jan. 30, 2023, which is assigned to the assignee hereof, and which is expressly incorporated by reference in its entirety herein.

### TECHNICAL FIELD

The following relates to one or more systems for memory, including staircase landing pads via rivets.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports staircase landing pads via rivets in accordance with examples as disclosed herein.

FIG. 2 illustrates an example of a memory architecture that supports staircase landing pads via rivets in accordance with examples as disclosed herein.

FIGS. 3A through 3K illustrate example structures that support staircase landing pads via rivets in accordance with examples as disclosed herein.

FIGS. 4 and 5 illustrate flowcharts showing a method or methods that support staircase landing pads via rivets in accordance with examples as disclosed herein.

### DETAILED DESCRIPTION

Some memory devices may include a staircase region. That is, a memory device may include a region in which a quantity of layers (e.g., conductive layers that are configured as word lines) of the memory device progressively decreases in length, forming a staircase structure. The staircase region may be configured to allow different pillars to couple with different layers of the memory device. For example, the memory device may include multiple conductive pillars that each couple respective conductive layers (e.g., word lines) with complementary metal oxide semiconductor (CMOS) circuitry of the memory device (e.g., one or more transistors). For example, memory devices may include a first conductive pillar, where one end of the first conductive pillar is in contact with a target word line, and another end of the first conductive pillar is coupled with a second conductive pillar that traverses a stack of materials of the memory device and couples to the CMOS circuitry.

To improve the capacity of memory devices, the layers of the memory devices may become smaller (e.g., thinner) to allow for a larger quantity of layers (e.g., and word lines or memory cells). As the layers become smaller, however, coupling (e.g., landing) the first conductive pillar on a target word line may become more difficult. For example, errors could occur during production of the memory devices, and the first conductive pillar may fail to couple with the target word line, may couple with a non-targeted word line, or may couple the target word line with other word lines. These errors may cause a shorting of two or more word lines of the memory devices or create an open circuit at a word line, resulting in defective memory devices.

Accordingly, the present disclosure provides memory architectures and manufacturing methods that may decrease the risk for word line short circuits or open circuits at a memory device. In accordance with examples as described herein, a memory device may include one or more rivets (e.g., rivet contacts, lateral word line contacts) that each couple a word line with a conductive pillar that traverses the layers (e.g., including a stack of materials) of the memory device. The use of the rivet may allow for a conductive pillar to be coupled with a target word line without requiring an end of the conductive pillar to be placed (e.g., landed) directly on the word line. In some cases, to couple each word line with a corresponding rivet, a thickness of the word line adjacent to the rivet that couples that word line with the conductive pillar may be larger than a thickness of the word line adjacent to other rivets (e.g., that each couple other word lines with other conductive pillars). The manufacturing methods described herein may thereby ensure that the conductive pillar is coupled with a target word line and isolated from other word lines. Additionally, the memory architecture described herein may allow for the target word line to be coupled with CMOS circuitry via a first conductive pillar without the use of a second conductive pillar, as the first conductive pillar may traverse the stack of materials and be coupled with the CMOS circuitry. Therefore, a total quantity of conductive pillars in the memory device may be reduced, and the risk of manufacturing errors may also be lowered.

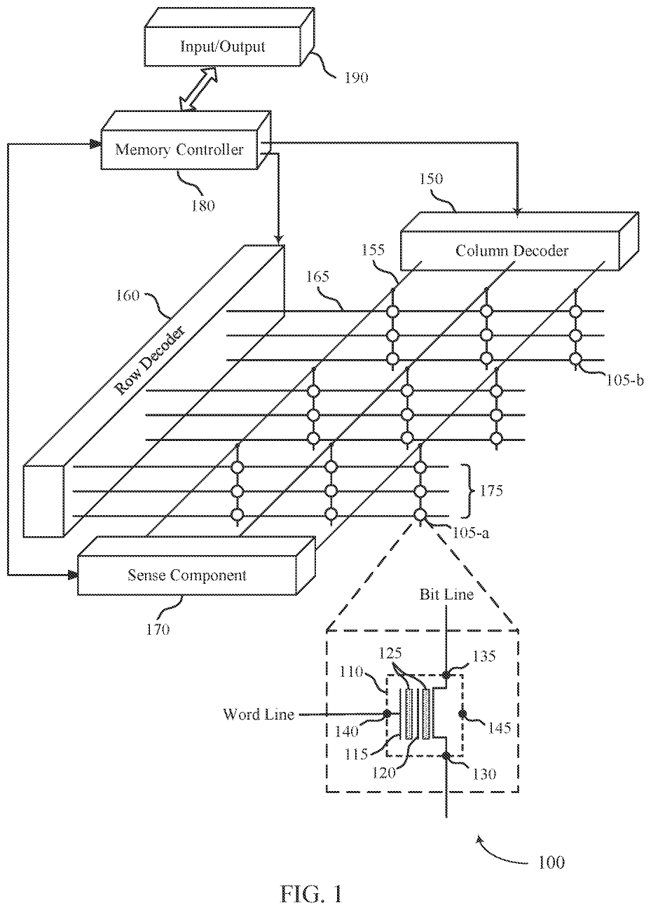

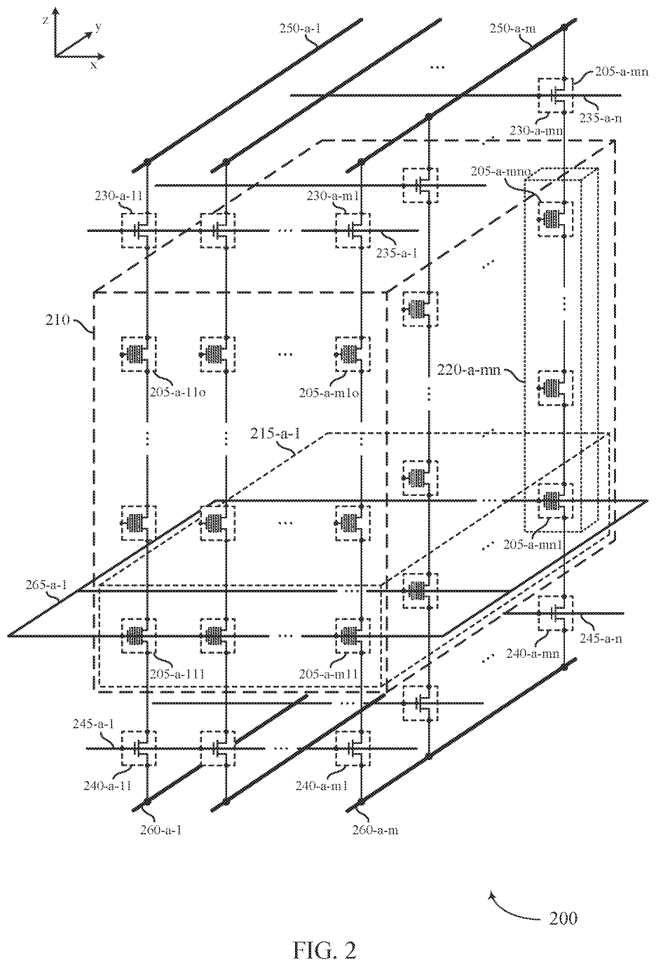

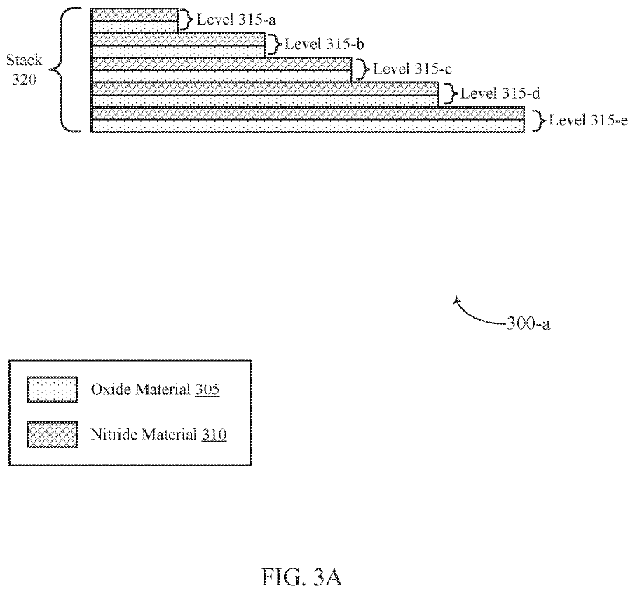

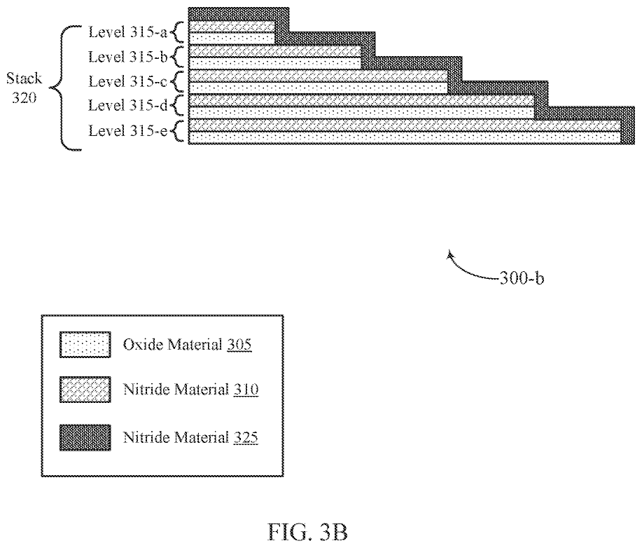

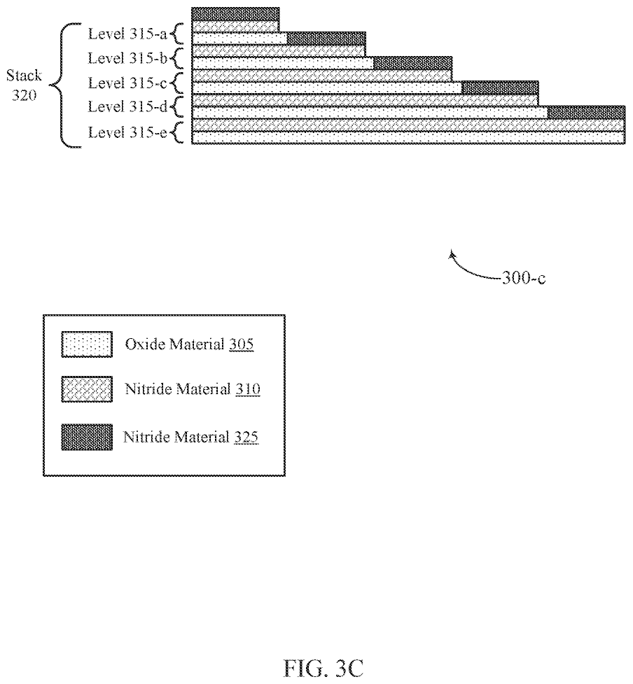

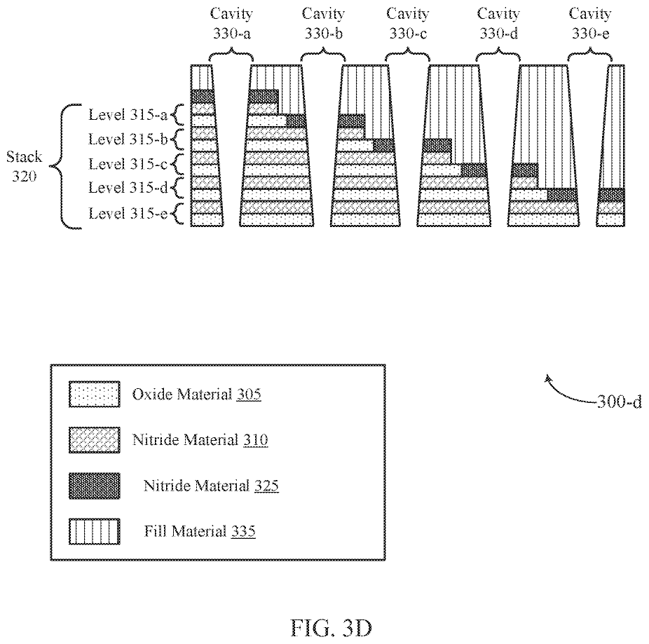

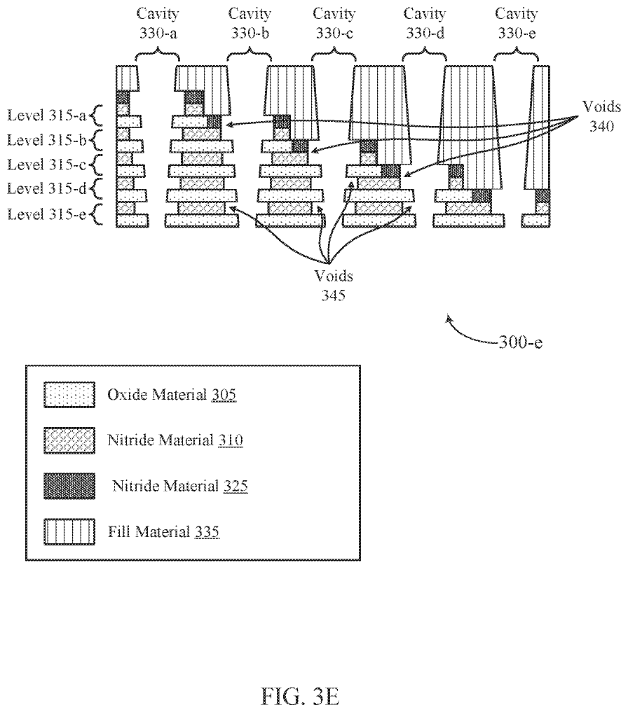

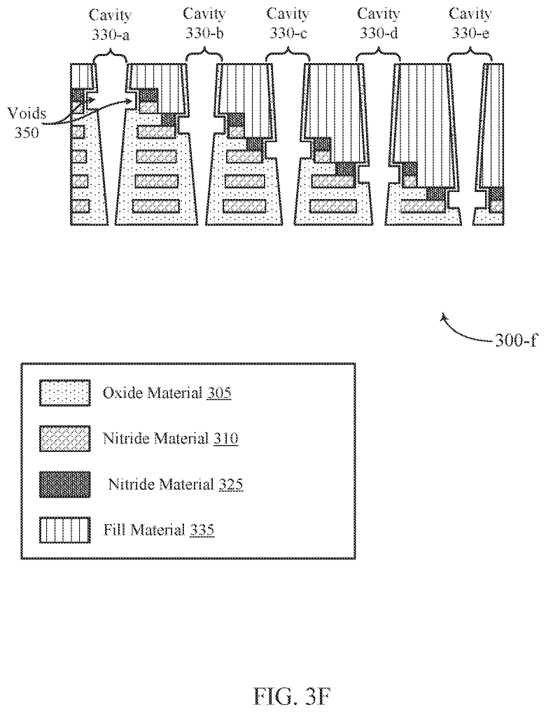

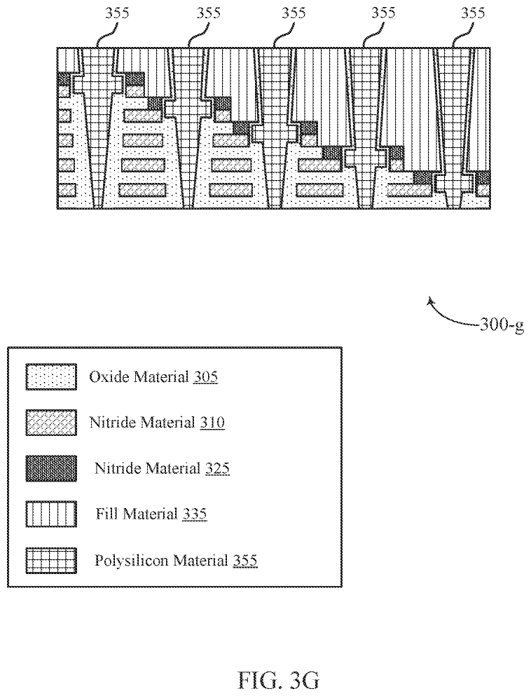

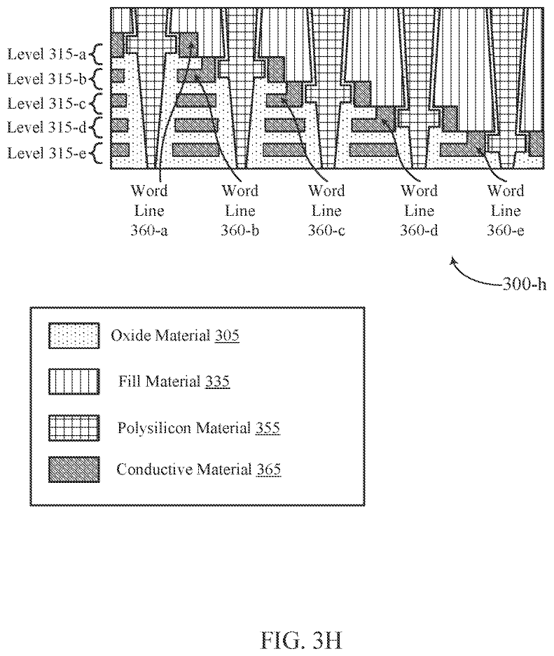

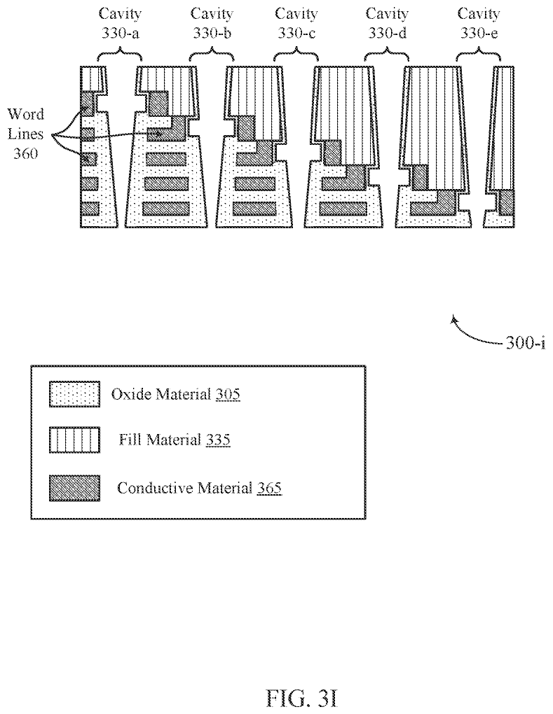

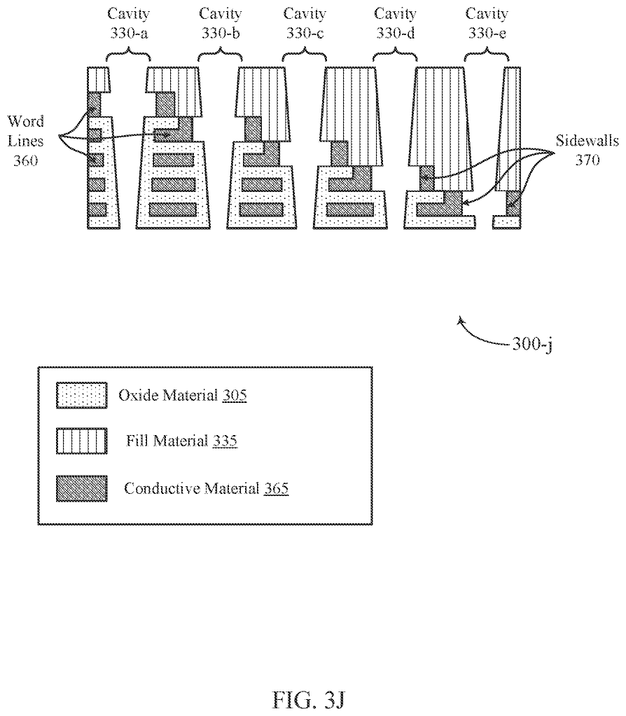

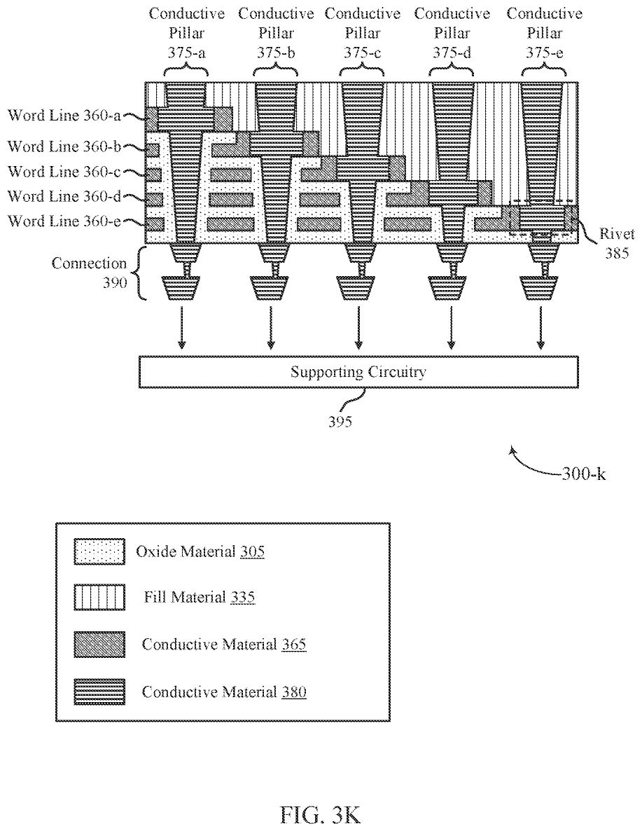

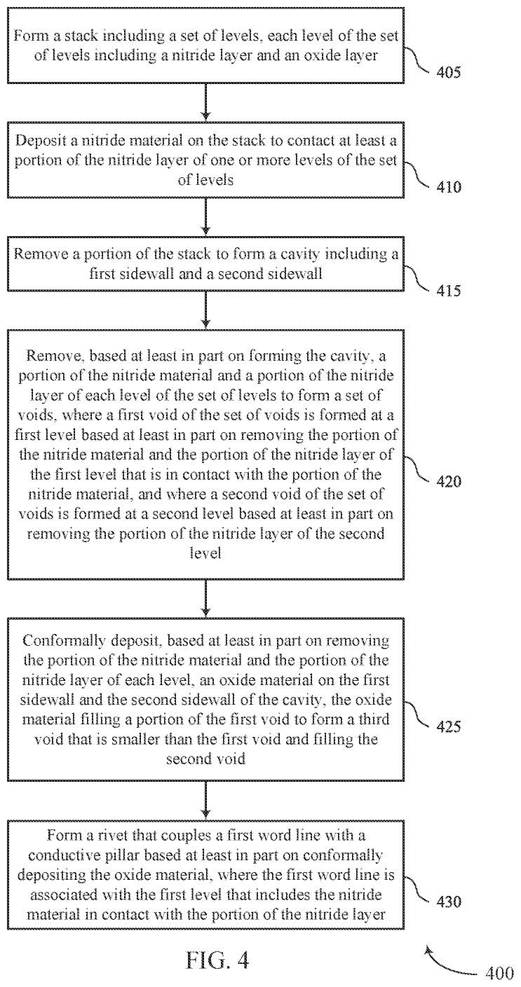

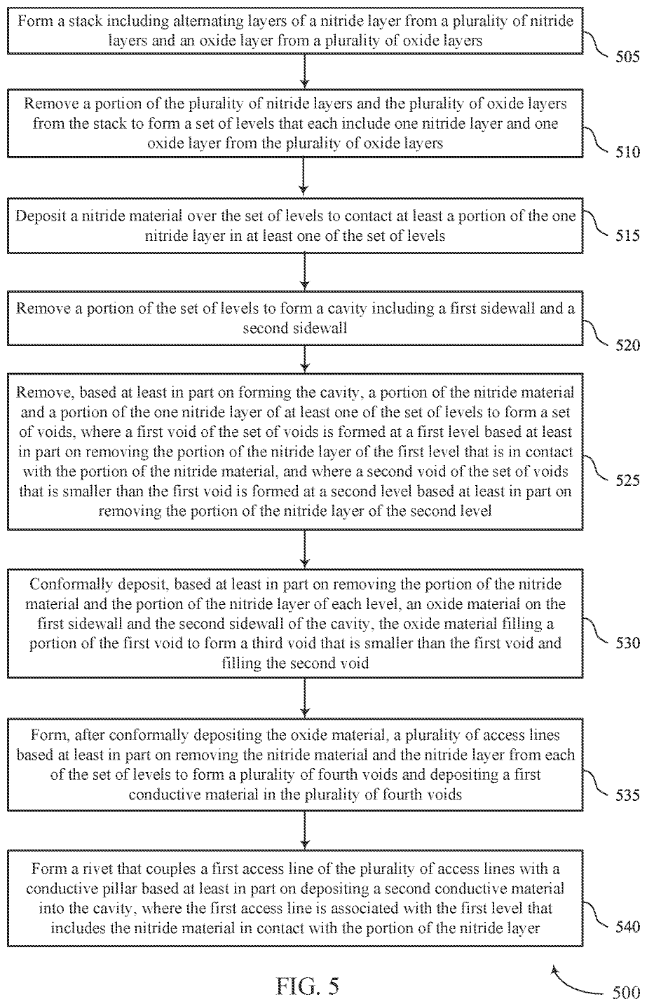

Features of the disclosure are initially described in the context of systems, devices, and circuits with reference to FIGS. 1 and 2. Features of the disclosure are described in the context of structures illustrating a manufacturing process with reference to FIGS. 3A through 3K. These and other features of the disclosure are further illustrated by and described in the context of flowcharts that relate to staircase landing pads via rivets with reference to FIGS. 4 and 5.

FIG. 1 illustrates an example of a memory device 100 that supports staircase landing pads via rivets in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a Each memory cell 105 may be programmed to store a logic value representing one or more bits of information. In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). A memory cell 105 may be written by applying different voltages (e.g., a voltage above a threshold or a voltage below a threshold) to memory cell 105 to store an electric charge on the charge trapping structure 120 and thereby cause the memory cell 105 store one of two or more possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

To improve capacity of memory devices 100, the layers of the memory device 100 may become smaller to allow for a larger quantity of word lines 165, for example. As the layers become smaller, however, the distance between word lines 165 may also decrease. This may make coupling (e.g., landing) a first conductive pillar of the memory device 100 on a target word line 165 to couple the target word line 165 with circuitry (e.g., CMOS circuitry) of the memory device 100 more difficult. For example, errors could occur during production of the memory device 100, and the first conductive pillar may fail to reach the target word line 165 or may couple the target word line 165 with other word lines 165. These errors may cause a shorting two or more word lines 165 of the memory device 100 or create an open circuit at a word line 165, resulting in a defective memory device 100.

Accordingly, the disclosure provides architectures and manufacturing methods that may decrease the risk for word line short circuits or open circuits at a memory device 100. In accordance with examples as described herein, the memory device 100 may include one or more rivets (e.g., rivet contacts) that may couple a word line 165 with a conductive pillar that traverses a stack of materials of the memory device 100. The use of the rivet may allow for a conductive pillar to be coupled with a target word line 165 without requiring an end of the conductive pillar to be placed (e.g., landed) directly on the word line 165. Thus, the manufacturing methods described herein may ensure the conductive pillar is coupled with a target word line 165 and isolated from other word lines 165. In some cases, to couple each word line 165 with a corresponding rivet, a thickness of the word line 165 adjacent to the rivet that couples that word line 165 with the conductive pillar may be larger than a thickness of the word line 165 adjacent to other rivets (e.g., that each couple other word lines 165 with other conductive pillars). Additionally, the architecture described herein may allow for the target word line 165 to be coupled with CMOS circuitry via a first conductive pillar without the use of a second conductive pillar, as the first conductive pillar may both traverse the stack of materials and be coupled with the CMOS circuitry. Therefore, total quantity of conductive pillars in the memory device 100 may be reduced, and the risk of manufacturing errors may also be lowered.

FIG. 2 illustrates an example of a memory architecture 200 that supports staircase landing pads via rivets in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they are the same or would be understood by a person having ordinary skill in the art to be similar. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110. NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with a same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of the page 215, but may not be erasable (e.g., reset to a logic 1 value) in accordance with the granularity, such as the granularity of the page 215. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause the memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as single-level cell (SLC) memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase the memory cells 205 in a block 210, as the memory cells 205 of the block 210 may share a common bulk.

To improve capacity of memory devices, the layers of the memory device may become smaller to allow for a larger quantity of word lines 265, for example. As the layers become smaller, however, the distance between word lines 265 may also decrease. This may make coupling (e.g., landing) a first conductive pillar of the memory device on a target word line 265 to couple the target word line 265 with circuitry (e.g., CMOS circuitry) of the memory device more difficult. For example, errors could occur during production of the memory device, and the first conductive pillar may fail to reach the target word line 265 or may couple the target word line 265 with other word lines 265. These errors may cause a shorting two or more word lines 265 of the memory device or create an open circuit at a word line 265, resulting in a defective memory device.

Accordingly, the disclosure provides architectures and manufacturing methods that may decrease the risk for word line short circuits or open circuits at a memory device. In accordance with examples as described herein, the memory device may include one or more rivets (e.g., rivet contacts, lateral word line contacts) that may couple a word line 265 with a conductive pillar that traverses a stack of materials of the memory device. The use of the rivet may allow for a conductive pillar to be coupled with a target word line 265 without requiring an end of the conductive pillar to be placed (e.g., landed) directly on the word line 265. Thus, the manufacturing methods described herein may ensure the conductive pillar is coupled with a target word line 265 and isolated from other word lines 265. In some cases, to couple each word line 265 with a corresponding rivet, a thickness of the word line 265 adjacent to the rivet or lateral word line contact that couples that word line 265 with the conductive pillar may be larger than a thickness of the word line 265 adjacent to other rivets (e.g., that each couple other word lines 265 with other conductive pillars). Additionally, the architecture described herein may allow for the target word line 265 to be coupled with CMOS circuitry via a first conductive pillar without the use of a second conductive pillar, as the first conductive pillar may both traverse the stack of materials and be coupled with the CMOS circuitry. Therefore, a total quantity of conductive pillars in the memory device may be reduced, and the risk of manufacturing errors may also be lowered.

FIGS. 3A through 3K illustrate examples of fabrication operations that may support staircase landing pads via rivets in accordance with examples as disclosed herein. For example, FIGS. 3A through 3K may illustrate operations for fabricating aspects of structures 300, which may be a portion of a memory device (e.g., a portion of the memory device 100 or the memory architecture 200). For example, the operations for fabricating aspects of structures 300 may correspond to operations for fabricating the staircase region of the memory device that is configured to allow different pillars (e.g., conductive pillars) to couple different access lines (e.g., word lines) of the memory device with supporting circuitry (e.g., CMOS circuitry). At a first end of the access line (e.g., word line) is a pillar that couples the access line with supporting circuitry, which is shown in FIGS. 3A through 3K. At a second end of the access line (opposite the first end), the access line may be coupled with a memory cell.

Each of FIGS. 3A through 3K may illustrate aspects of the structure 300 after different subsets of the fabrication operations for forming the structure 300 (e.g., illustrated as the structure 300-a after a first set of one or more manufacturing operations, as a structure 300-b after a second set of one or more manufacturing operations, and so on). Although the structure 300 illustrates examples of some relative dimensions and quantities of various features, aspects of the structure 300 may be implemented with other relative dimensions or quantities of such features in accordance with examples as disclosed herein.

Operations illustrated in and described with reference to FIGS. 3A through 3K may be performed by a manufacturing system, such as a semiconductor fabrication system configured to perform additive operations such as deposition or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 3A illustrates an example of a structure 300-a after a first set of one or more manufacturing operations that support staircase landing pads via rivets in accordance with examples as disclosed herein. The structure 300-a may include a stack 320 that includes a set of levels 315. Each level 315 may include a layer of an oxide material 305 and a layer of a nitride material 310. In some examples, the oxide material 305 may be a silicon oxide material, among other examples. Similarly, the nitride material 310 may be a silicon nitride material, among other examples. In some examples, the nitride material 310 may be a precursor to a conductive material which may form word lines of a completed memory device. For example, the nitride material 310 may subsequently be removed (e.g., etched) and replaced with a conductive material, as described in more detail herein, with reference to FIG. 3H. In some examples, the oxide material 305 may form a dielectric material in the memory device and may isolate word lines from each other.

To form the stack 320, interleaving layers of the oxide material 305 and the nitride material 310 may be formed. For example, a first layer of the oxide material 305 may be deposited (e.g., the layer of the oxide material 305 in the level 315-e may be deposited), and the first layer of the nitride material 310 may be deposited over the first layer of the oxide material 305. A similar set of operations may be performed (e.g., depositing a layer of the oxide material 305 followed by depositing a layer of the nitride material 310 over the layer of the oxide material 305) until the stack 320 is formed. Thus, a stack 320 that includes alternating layers of the oxide material 305 and the nitride material 310 may be formed.

After forming the stack 320, the first set of one or more manufacturing operations may include additional manufacturing operations to form the set of levels 315. That is, the stack 320 of materials may be modified to include one or more levels 315. For example, a portion of each of a subset of layers of the oxide material 305 and a subset of layers of the nitride material 310 may be removed to form the level 315-a, the level 315-b, the level 315-c, the level 315-d, and the level 315-e. After removing the portion of each of the subset of layers, the levels 315 may each be of a same height and width. For example, the levels 315 may each have a height equivalent to the height of one layer of the oxide material 305 and one layer of the nitride material 310. Additionally, the widths of each level 315 may vary, as illustrated in FIG. 3A, so that the structure 300-a forms a staircase structure. Aspects of the disclosure may be implemented for different heights, widths, and quantities of levels 315, and the heights, widths, and quantities of levels 315 shown in FIG. 3A are for illustrative purposes. In some examples, the structure 300-a may represent a staircase region (e.g., of a 3D NAND memory device).

FIG. 3D illustrates an example of a structure 300-b after a second set of one or more manufacturing operations that support staircase landing pads via rivets in accordance with examples as disclosed herein. The second set of operations may include operations that support depositing the nitride material 325 over the structure 300-a to form the structure 300-b. For example, the nitride material 325 may be a conformal nitride liner that conformally lines the stack 320. In this example, the second set of operations may include conformally depositing the nitride material 325 over the stack 320. In some cases, the nitride material 325 may be a same material as the nitride material 310. Additionally, or alternatively, the nitride material 325 may be different from the nitride material 310. For example, the nitride material 325 may include another type of silicon nitride material (or another type of sacrificial material) that is different than the nitride material 310.

After depositing the nitride material 325 over the structure 300-a, the nitride material 325 may contact at least a portion of a top surface of the nitride material 310 in each level 315. For example, the nitride material 325 may contact a portion of the top surface of the nitride material 310 in the level 315-a, a portion of the top surface of the nitride material 310 in the level 315-b, a portion of the top surface of the nitride material 310 in the level 315-c, a portion of the top surface of the nitride material 310 in the level 315-d, and a portion of the top surface of the nitride material 310 in the level 315-e. The nitride material 325 may additionally contact sidewalls of both the nitride material 310 and the oxide material 305 of each level 315.

FIG. 3C illustrates an example of a structure 300-c after a third set of one or more manufacturing operations that support staircase landing pads via rivets in accordance with examples as disclosed herein. The third set of operations may include operations that support removing portions of the nitride material 325 from the stack 320 to expose sidewalls of the nitride material 310 in each level 315. For example, the third set of operations may include an etching procedure (e.g., a wet etching process) to selectively remove the nitride material 325 from sidewalls of the stack 320. After performing the third set of operations, sidewalls of the nitride material 310 in each level 315 may be exposed. Additionally, a portion of the top surface of the oxide material 305 in each level 315 may be exposed.

FIG. 3D illustrates an example of a structure 300-d after a fourth set of one or more manufacturing operations that support staircase landing pads via rivets in accordance with examples as disclosed herein. The fourth set of operations may include operations that support forming a set of cavities 330 in the stack 320 to form the structure 300-d.

In some cases, the fourth set of operations may include operations to deposit a fill material 335 over the structure 300-c. The fill material 335 may fill gaps above the staircase region relative to other portions of the structure. For example, the fill material 335 may be deposited on top of the structure 300-c to form the structure 300-d having a substantially uniform height across the staircase region. In the example of the structure 300-d, the fill material may contact a top surface of the nitride material 325, sidewalls of the nitride material 325, sidewalls of the nitride material 310 in each level 315, and a portion of a top surface of the oxide material 305 in each level 315. In some examples, the fill material 335 may be an example of a dielectric material, such as an oxide material. In some examples, the fill material 335 may be deposited on top of the liner material (e.g., the oxide liner) if present. In these examples, the fourth set of operations may additionally include conformally depositing an oxide liner material over the structure 300-c (e.g., in contact with the nitride material 325). Then, the fourth set of operations may include depositing the fill material 335 over the oxide liner material.

After depositing the fill material 335 over the structure 300-c, the fourth set of operations may include operations to form each of the cavities 330. For example, the fourth set of operations may include an etching procedure (e.g., a dry etching process) to form the cavities 330. To form each cavity 330, a portion of the fill material 335 may be removed, a portion of the nitride material 325 may be removed, and a portion of the nitride material 310 and the oxide material 305 in each level 315 may be removed. In some cases, each of the cavities 330-a, 330-b, 330-c, 330-d, and 330-e may extend through the stack 320 (e.g., substantially perpendicularly to each of the levels 315) and expose supporting circuitry that is positioned below the structure 300-d (e.g., including CMOS circuitry). The cavities 330 may be precursors for forming the conductive pillars 375.

Each cavity 330 may be defined by a first sidewall and a second sidewall (e.g., each cavity 33 may extend from the first sidewall to the second sidewall). The first and second sidewalls may include alternating layers of the oxide material 305 and the nitride material 310, the nitride material 325, and the fill material 335.

FIG. 3E illustrates an example of a structure 300-e after a fifth set of one or more manufacturing operations that support staircase landing pads via rivets in accordance with examples as disclosed herein. The fifth set of operations may include operations that support forming the voids 340 and 345 in the stack 320 to form the structure 300-e. For example, the fifth set of operations may include an etching procedure (e.g., a wet etching process) to selectively remove portions of the nitride material 310 and the nitride material 325 (and not the oxide material 305) from the structure 300-d to form the structure 300-e. In some cases, the etching procedure may be a wet recession process. After performing the etching procedure, a set of voids 340 and 345 may be formed in the structure 300-e. While the structure 300-e illustrates voids 340 and 345 with substantially vertical sidewalls, the sidewalls of the voids 340 and 345 may instead be sloped. Additionally, or alternatively, sidewalls of the voids 340 and 345 may not be a straight line, but rather curved.

The set of voids 340 and 345 may include voids 340 and 345 that are different thicknesses. For example, the voids 340 that are formed based on removing both the nitride material 325 and the nitride material 310 may thicker (e.g., may extend a larger vertical distance) than the voids 345 that are formed based on removing the nitride material 310 (e.g., and not based on removing the nitride material 325). In some cases, each level 315 may include a single void 340 that is thicker and formed based on removing the nitride material 325 and the nitride material 310. Additionally, the levels 315-a, 315-b, 315-c, and 315-d may also include one or more voids 345 that are less thick (e.g., that extend a shorter vertical distance) and formed based on removing the nitride material 310 (and not based on removing the nitride material 325). Additionally, or alternatively, each cavity 330 may include a single void 340 that is thicker; and the cavities 330-a, 330-b, 330-c, and 330-d may also include one or more voids 345 that are less thick. The voids 340 and 345 may be used in later processes to form a rivet to couple a single access line with a single pillar and also isolate the other access lines from the single pillar.

FIG. 3F illustrates an example of a structure 300-f after a sixth set of one or more manufacturing operations that support staircase landing pads via rivets in accordance with examples as disclosed herein. The sixth set of operations may include operations that support depositing an oxide liner (e.g., that includes the oxide material 305) in each of the cavities 330 of the structure 300-e to form the structure 300-f. For example, the sixth set of operations may include a conformal deposition of the oxide material 305 in each of the cavities 330. After the conformal deposition of the oxide material 305 in the cavities 330 of the structure 300-e, the exposed surfaces of the cavities 330 may be lined with a layer of the oxide material 305 that is substantially uniform in thickness. In some cases, the sixth set of operations may include an atomic layer deposition process to conformally deposit an oxide liner of that includes the oxide material 305. As described in later processes, the oxide liner may insulate some access lines from a pillar. The thickness of the oxide liner may facilitate the formation of a rivet that couples the pillar with an access line and may insulate other access lines from that same pillar.

After depositing the oxide material 305, the oxide material 305 that is conformally deposited to form the structure 300-f may be in contact with sidewalls of the fill material 335; sidewalls of the nitride material 310 and 325; and sidewalls, a portion of a top surface, and a portion of a bottom surface of the oxide material 305 in each level 315. In some cases, after depositing the oxide material 305 to form the structure 300-f, the sidewalls of the cavities 330 may not be exposed, but instead may be in contact with the oxide material 305.

In some cases, the thickness of the oxide material 305 that is conformally deposited to line the exposed surfaces of the cavities 330 in the structure 300-e to form the structure 300-f may be larger than a thickness that is equal to half of the thickness of the voids 345 (e.g., in the structure 300-d). As a result, the oxide material 305 may fill the voids (or may substantially fill the voids 345) and the structure 300-f may not include any voids 345. Additionally, the thickness of the oxide material 305 that is conformally deposited to line the exposed surfaces of the cavities 330 in the structure 300-e may be less than a thickness that is equal to half of the thickness of the voids 340 (e.g., in the structure 300-d). As a result, the oxide material 305 may line the voids 340 to form voids 350 that are smaller than the voids 340, but may not fill the voids 340.

FIG. 3G illustrates an example of a structure 300-g after a seventh set of one or more manufacturing operations that support staircase landing pads via rivets in accordance with examples as disclosed herein. The seventh set of operations may include operations that support depositing a polysilicon material 355 in each of the cavities 330 of the structure 300-f to form the structure 300-g. In some cases, depositing the polysilicon material 355 (or another material that may be a sacrificial material) to fill the cavities 330 to form the structure 300-g.

FIG. 3H illustrates an example of a structure 300-h after an eighth set of one or more manufacturing operations that support staircase landing pads via rivets in accordance with examples as disclosed herein. The eighth set of operations may include operations that support forming the word lines 360. For example, the eight set of operations may include a replacement gate process, where the nitride material 310 and the nitride material 325 are replaced with the conductive material 365 to form the word lines 360. In some cases, the eight set of operations may include one or more recessing operations to remove the nitride materials 310 and 325 from the structure 300-g. Additionally, or alternatively, the eight set of operations may include an etching process (e.g., a wet etching process) that is selective to the nitride materials 310 and 325 (e.g., while not removing the oxide material 305, the fill material 335, or the polysilicon material 355) and removes the nitride materials 310 and 325 from the structure 300-g. In these cases, the eight set of operations may additionally include a deposition of the conductive material 365. Here, the conductive material 365 may be deposited into voids formed by removing the nitride materials 310 and 325 from the structure 300-g to form the structure 300-h. In some other examples, the eight set of operations may include a metallization process, where the nitride materials 310 and 325 are metallized from the nitride materials 310 and 325 to the conductive material 365.

After the eight set of operations, the structure 300-h may include a set of word lines 360, each associated with a respective level 315. For example, the word line 360-a may be associated with the level 315-a, the word line 360-b may be associated with the level 315-b, the word line 360-c may be associated with the level 315-c, the word line 360-d may be associated with the level 315-d, and the word line 360-e may be associated with the level 315-e. Additionally, each word line 360 may include a portion of the word line 360 that is thicker than other portions of that word line 360. For example, the portion of the word line 360 that is formed based on replacing the nitride material 310 and the nitride material 325 with the conductive material 365 may be thicker than portions of the word line 360 that is formed based on replacing the nitride material 310 that is not in contact with the nitride material 325.

FIG. 3I illustrates an example of a structure 300-i after a ninth set of one or more manufacturing operations that support staircase landing pads via rivets in accordance with examples as disclosed herein. The ninth set of operations may include operations that support re-forming the set of cavities 330 in the structure 300-h to form the structure 300-h. For example, the ninth set of operations may include an etching procedure (e.g., a dry etching process, a wet etching process) to form the cavities 330. Additionally, or alternatively, the ninth set of operations may include a masking operation, where portions of the structure 300-h are selectively masked. For example, portions of a top surface of the structure 300-h that are not above the polysilicon material 355 may be masked. Additionally, portions of a top surface of the structure 300-h that are filled with the polysilicon material 355 that are intended as support vias may be masked. Then, unmasked portions of the structure 300-h may be etched to form the cavities 330. In some cases, the cavities 330 may expose the oxide liner that includes the oxide material 305. That is, sidewalls of the cavities 330 may contact the oxide liner.

In some examples, one or more of the pillars of the polysilicon material 355 (e.g., illustrated in the structure 300-h) may be used to form support vias (e.g., electrically inactive support vias), which may act as a support for the structure 300-h and the completed memory device. For example, the pillars of the polysilicon material 355 that are below masked portions of the structure 300-h may form support vias in the completed memory device.

FIG. 3J illustrates an example of a structure 300-j after a tenth set of one or more manufacturing operations that support staircase landing pads via rivets in accordance with examples as disclosed herein. The tenth set of operations may include operations that includes an etching procedure to expose a subset of the sidewalls 370 of the word lines 360, while leaving the remaining sidewalls of the word lines 360 insulated (e.g., by the oxide material 305). For example, the tenth set of operations may include a conformal wet etching procedure to remove a substantially uniform thickness of the oxide material 305 from each of the cavities 330. In some cases, the thickness of the oxide material 305 that is removed from the surfaces in the cavities 330 of the structure 300-i may be greater than a thickness of the oxide material 305 that is lining one word line 360 in each cavity 330, but less than a thickness of the oxide material 305 lining a remaining quantity of word lines 360 in each cavity 330. As a result, after the tenth set of operations, sidewalls 370 of one word line 360 in each cavity may be exposed, while the sidewalls 370 of other word lines 360 that are adjacent to the cavity 330 may remain insulated by remaining portions of the oxide material 305. In some instances, the one word line 360 that has a larger thickness adjacent to a cavity 330 (e.g., in the structure 300-i) may be exposed in the structure 300-h. Additionally, any word lines 360 that have a smaller thickness adjacent to the cavity 330 (e.g., in the structure 300-i) may remain insulated from the cavity 330 by remaining portion of the oxide material 305 in the structure 300-h.

FIG. 3K illustrates an example of a structure 300-k after an eleventh set of one or more manufacturing operations that support staircase landing pads via rivets in accordance with examples as disclosed herein. The eleventh set of operations may include operations that that support forming the conductive pillars 375 that each couple one word line 360 with the supporting circuitry 395 (e.g., via a rivet 385 and a connection 390). For example, the eleventh set of operations may include depositing the conductive material 380 in each of the cavities 330 of the structure 300-j to form the structure 300-k. In some other examples, the eleventh set of operations may include depositing another sacrificial material (e.g., a carbon material or a carbon nitride material) into the cavities 330 of the structure 300-j; selectively masking the structure 300-j (e.g., cavities 330 filled with sacrificial material that are intended as support vias may be masked to avoid metallization of the support vias); then performing a metallization procedure on the unmasked cavities 330 filled with the sacrificial material to cause the sacrificial material to transform into the conductive material 380.

After the eleventh set of operations, the structure 300-k may include a set of word lines 360 that are each coupled with one of the conductive pillars 375 via a corresponding rivet 385. For example, the word line 360-a may be coupled with the (e.g., in electronic communication with) the conductive pillar 375-a via a first rivet 385, the word line 360-b may be coupled with the conductive pillar 375-b via a second rivet 385, the word line 360-c may be coupled with the conductive pillar 375-c via a third rivet 385, the word line 360-d may be coupled with the conductive pillar 375-d via a fourth rivet 385, and the word line 360-e may be coupled with the conductive pillar 375-e via a fifth rivet 385. Each rivet 385 may correspond to a lateral word line 360 contact. That is, each rivet 385 may laterally contact a word line 360 and couple the word line 360 with a conductive pillar 375. In some cases, a thickness of each word line 360 adjacent to the conductive pillar 375 that it is coupled with may be greater when compared to a thickness of other word lines 360 (e.g., that are not coupled with that conductive pillar 375) adjacent to that conductive pillar 375. For example, the word line 360-a may be thicker adjacent to the conductive pillar 375-a (e.g., that the word line 360-a is coupled to) as compared to a thickness of the word lines 360-b, 360-c, 360-d, and 360-e adjacent to the conductive pillar 375-a.

In some cases, while each word line 360 is coupled with one of the conductive pillars 375, each word line 360 is also isolated from each remaining conductive pillar 375. For example, the word line 360-e may be coupled with the conductive pillar 375-e, and isolated from the conductive pillars 375-a, 375-b, 375-c, and 375-d via the oxide material 305.

In some examples, the conductive pillar 375 may each be coupled with respective connections 390. The connections 390 may couple the respective conductive pillars 375 to the supporting circuitry 395 of the memory device, such as CMOS circuitry.

Accordingly, the manufacturing methods described herein, with reference to FIGS. 3A-3K, may allow for formation of the staircase structure of a memory device in which a word line 360 is coupled with a conductive pillar 375 via a rivet 385, while the conductive pillar 375 is isolated from other word lines 360. Each conductive pillar 375 may traverse the stack of materials of the memory device and be coupled with the supporting circuitry 395, and each conductive pillar 375 may travel in a direction perpendicular to the word lines 360. The memory device may be operable to couple the word line 360 to the supporting circuitry 395 via the rivet 385, the conductive pillar 375, and the connections 390. This would allow for a word line 360 to be coupled with the supporting circuitry 395 without the use of multiple conductive pillars 375. Therefore, a total quantity of conductive pillars 375 in the memory device may be reduced, and the risk of manufacturing errors may also be lowered by using the rivet 385 to couple a conductive pillar 375 to a word line 360. One end of the word line 360 may be coupled with a conductive pillar 375 while a different end of the word line 360 (not shown) may be coupled with a NAND channel and may form a NAND memory cell.

FIG. 4 illustrates a flowchart showing a method 400 that supports staircase landing pads via rivets in accordance with examples as disclosed herein. The operations of method 400 may be implemented by a manufacturing system or its components as described herein. For example, the operations of method 400 may be performed by a manufacturing system as described with reference to FIGS. 1 through 3K. In some examples, a manufacturing system may execute a set of instructions to control the functional elements of the device to perform the described functions. Additionally, or alternatively, the manufacturing system may perform aspects of the described functions using special-purpose hardware.

At 405, the method may include forming a stack including a set of levels, each level of the set of levels including a nitride layer and an oxide layer. The operations of 405 may be performed in accordance with examples as disclosed herein. In some examples, aspects of the operations of 405 may be performed in accordance with examples as disclosed herein.

At 410, the method may include depositing a nitride material on the stack to contact at least a portion of the nitride layer of one or more levels of the set of levels. The operations of 410 may be performed in accordance with examples as disclosed herein.

At 415, the method may include removing a portion of the stack to form a cavity including a first sidewall and a second sidewall. The operations of 415 may be performed in accordance with examples as disclosed herein.

At 420, the method may include removing, based at least in part on forming the cavity, a portion of the nitride material and a portion of the nitride layer of each level of the set of levels to form a set of voids, where a first void of the set of voids is formed at a first level based at least in part on removing the portion of the nitride material and the portion of the nitride layer of the first level that is in contact with the portion of the nitride material, and where a second void of the set of voids is formed at a second level based at least in part on removing the portion of the nitride layer of the second level. The operations of 420 may be performed in accordance with examples as disclosed herein.

At 425, the method may include conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void. The operations of 425 may be performed in accordance with examples as disclosed herein.

At 430, the method may include forming a rivet that couples a first word line with a conductive pillar based at least in part on conformally depositing the oxide material, where the first word line is associated with the first level that includes the nitride material in contact with the portion of the nitride layer. The operations of 430 may be performed in accordance with examples as disclosed herein.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a stack including a set of levels, each level of the set of levels including a nitride layer and an oxide layer; depositing a nitride material on the stack to contact at least a portion of the nitride layer of one or more levels of the set of levels; removing a portion of the stack to form a cavity including a first sidewall and a second sidewall; removing, based at least in part on forming the cavity, a portion of the nitride material and a portion of the nitride layer of each level of the set of levels to form a set of voids, where a first void of the set of voids is formed at a first level based at least in part on removing the portion of the nitride material and the portion of the nitride layer of the first level that is in contact with the portion of the nitride material, and where a second void of the set of voids is formed at a second level based at least in part on removing the portion of the nitride layer of the second level; conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void; and forming a rivet that couples a first word line with a conductive pillar based at least in part on conformally depositing the oxide material, where the first word line is associated with the first level that includes the nitride material in contact with the portion of the nitride layer.

Aspect 2: The method, apparatus, or non-transitory computer-readable medium of aspect 1, further including operations, features, circuitry, logic, means, or instructions, or any combination thereof for forming, after conformally depositing the oxide material, a plurality of word lines including at least the first word line and a second word line based at least in part on removing the nitride material and the nitride layer from each level of the set of levels to form a plurality of fourth voids and depositing a first conductive material in the plurality of fourth voids, where forming the rivet occurs after forming the plurality of word lines.

Aspect 3: The method, apparatus, or non-transitory computer-readable medium of aspect 2, where a first thickness of the first word line adjacent to the cavity is greater than a second thickness of the second word line adjacent to the cavity.

Aspect 4: The method, apparatus, or non-transitory computer-readable medium of any of aspects 2 through 3, further including operations, features, circuitry, logic, means, or instructions, or any combination thereof for removing, after forming the plurality of word lines, a portion of the oxide material from the first sidewall and the second sidewall of the cavity, where removing the portion of the oxide material from the third void exposes sidewalls of the first word line, and where removing the portion of the oxide material from the second void decreases a thickness of a remaining portion of the oxide material in the second void that contacts the second word line.

Aspect 5: The method, apparatus, or non-transitory computer-readable medium of aspect 4, where removing the portion of the oxide material further includes operations, features, circuitry, logic, means, or instructions, or any combination thereof for performing a wet etching process to conformally remove the portion of the oxide material from the first sidewall and the second sidewall of the cavity.

Aspect 6: The method, apparatus, or non-transitory computer-readable medium of any of aspects 4 through 5, further including operations, features, circuitry, logic, means, or instructions, or any combination thereof for depositing, based at least in part on removing the portion of the oxide material, a second conductive material into the cavity to form the conductive pillar and the rivet, where the second conductive material contacts the first word line and is electrically isolated from the second word line by the remaining portion of the oxide material.

Aspect 7: The method, apparatus, or non-transitory computer-readable medium of any of aspects 1 through 6, further including operations, features, circuitry, logic, means, or instructions, or any combination thereof for depositing a polysilicon material in the cavity after conformally depositing the oxide material, where forming the rivet occurs after depositing the polysilicon material in the cavity.

Aspect 8: The method, apparatus, or non-transitory computer-readable medium of any of aspects 1 through 7, further including operations, features, circuitry, logic, means, or instructions, or any combination thereof for performing a wet etching process to remove the nitride material from sidewalls of the stack to expose a sidewall of the nitride layer of the one or more levels of the set of levels that contacts the nitride material, where forming the cavity is based at least in part on performing the wet etching process.

Aspect 9: The method, apparatus, or non-transitory computer-readable medium of any of aspects 1 through 8, where forming the stack includes operations, features, circuitry, logic, means, or instructions, or any combination thereof for depositing each nitride layer on each oxide layer to form the stack including a set of oxide layers interleaving a set of nitride layers.

Aspect 10: The method, apparatus, or non-transitory computer-readable medium of aspect 9, further including operations, features, circuitry, logic, means, or instructions, or any combination thereof for removing a portion of the set of nitride layers and the set of oxide layers to form each level of the set of levels, where the portion includes a first subset of the set of oxide layers and a first subset of the set of nitride layers, and where depositing the nitride material occurs after forming each level of the set of levels.

Aspect 11. The method, apparatus, or non-transitory computer-readable medium of any of aspects 1 through 10, where each level of the set of levels includes a respective height and a respective width.

Aspect 12: The method, apparatus, or non-transitory computer-readable medium of any of aspects 1 through 11, further including operations, features, circuitry, logic, means, or instructions, or any combination thereof for depositing a second nitride material over the stack after depositing the nitride material over the stack, where forming the cavity further includes removing a portion of the second nitride material.

FIG. 5 illustrates a flowchart showing a method 500 that supports staircase landing pads via rivets in accordance with examples as disclosed herein. The operations of method 500 may be implemented by a manufacturing system or its components as described herein. For example, the operations of method 500 may be performed by a manufacturing system as described with reference to FIGS. 1 through 3K. In some examples, a manufacturing system may execute a set of instructions to control the functional elements of the device to perform the described functions. Additionally, or alternatively, the manufacturing system may perform aspects of the described functions using special-purpose hardware.

At 505, the method may include forming a stack including alternating layers of a nitride layer from a plurality of nitride layers and an oxide layer from a plurality of oxide layers. The operations of 505 may be performed in accordance with examples as disclosed herein.

At 510, the method may include removing a portion of the plurality of nitride layers and the plurality of oxide layers from the stack to form a set of levels that each include one nitride layer and one oxide layer from the plurality of oxide layers. The operations of 510 may be performed in accordance with examples as disclosed herein.

At 515, the method may include depositing a nitride material over the set of levels to contact at least a portion of the one nitride layer in at least one of the set of levels. The operations of 515 may be performed in accordance with examples as disclosed herein.

At 520, the method may include removing a portion of the set of levels to form a cavity including a first sidewall and a second sidewall. The operations of 520 may be performed in accordance with examples as disclosed herein.

At 525, the method may include removing, based at least in part on forming the cavity, a portion of the nitride material and a portion of the one nitride layer of at least one of the set of levels to form a set of voids, where a first void of the set of voids is formed at a first level based at least in part on removing the portion of the nitride layer of the first level that is in contact with the portion of the nitride material, and where a second void of the set of voids that is smaller than the first void is formed at a second level based at least in part on removing the portion of the nitride layer of the second level. The operations of 525 may be performed in accordance with examples as disclosed herein.

At 530, the method may include conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void. The operations of 530 may be performed in accordance with examples as disclosed herein.

At 535, the method may include forming, after conformally depositing the oxide material, a plurality of access lines based at least in part on removing the nitride material and the nitride layer from each of the set of levels to form a plurality of fourth voids and depositing a first conductive material in the plurality of fourth voids. The operations of 535 may be performed in accordance with examples as disclosed herein.

At 540, the method may include forming a rivet that couples a first access line of the plurality of access lines with a conductive pillar based at least in part on depositing a second conductive material into the cavity, where the first access line is associated with the first level that includes the nitride material in contact with the portion of the nitride layer. The operations of 540 may be performed in accordance with examples as disclosed herein.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 13: A method, apparatus, or non-transitory computer-readable medium including operations, features, circuitry, logic, means, or instructions, or any combination thereof for forming a stack including alternating layers of a nitride layer from a plurality of nitride layers and an oxide layer from a plurality of oxide layers; removing a portion of the plurality of nitride layers and the plurality of oxide layers from the stack to form a set of levels that each include one nitride layer and one oxide layer from the plurality of oxide layers; depositing a nitride material over the set of levels to contact at least a portion of the one nitride layer in at least one of the set of levels; removing a portion of the set of levels to form a cavity including a first sidewall and a second sidewall; removing, based at least in part on forming the cavity, a portion of the nitride material and a portion of the one nitride layer of at least one of the set of levels to form a set of voids, where a first void of the set of voids is formed at a first level based at least in part on removing the portion of the nitride layer of the first level that is in contact with the portion of the nitride material, and where a second void of the set of voids that is smaller than the first void is formed at a second level based at least in part on removing the portion of the nitride layer of the second level; conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void; forming, after conformally depositing the oxide material, a plurality of access lines based at least in part on removing the nitride material and the nitride layer from each of the set of levels to form a plurality of fourth voids and depositing a first conductive material in the plurality of fourth voids; and forming a rivet that couples a first access line of the plurality of access lines with a conductive pillar based at least in part on depositing a second conductive material into the cavity, where the first access line is associated with the first level that includes the nitride material in contact with the portion of the nitride layer.

Aspect 14: The method, apparatus, or non-transitory computer-readable medium of aspect 13, where a first thickness of the first access line adjacent to the cavity is greater than a second thickness of a second access line adjacent to the cavity.

Aspect 15: The method, apparatus, or non-transitory computer-readable medium of any of aspects 13 through 14, further including operations, features, circuitry, logic, means, or instructions, or any combination thereof for removing, after forming the plurality of access lines, a portion of the oxide material from the first sidewall and the second sidewall of the cavity, where removing the portion of the oxide material from the third void exposes sidewalls of the first access line, and where removing the portion of the oxide material from the second void decreases a thickness of a remaining portion of the oxide material in the second void that contacts a second access line.

Aspect 16: The method, apparatus, or non-transitory computer-readable medium of aspect 15, further including operations, features, circuitry, logic, means, or instructions, or any combination thereof for depositing, based at least in part on removing the portion of the oxide material, the second conductive material into the cavity to form the conductive pillar and the rivet, where the second conductive material contacts the first access line and is electrically isolated from the second access line by the remaining portion of the oxide material.

Aspect 17: The method, apparatus, or non-transitory computer-readable medium of any of aspects 13 through 16, further including operations, features, circuitry, logic, means, or instructions, or any combination thereof for depositing a polysilicon material in the cavity after forming the plurality of access lines, where forming the rivet occurs after depositing the polysilicon material in the cavity.

Aspect 18: The method, apparatus, or non-transitory computer-readable medium of any of aspects 13 through 17, further including operations, features, circuitry, logic, means, or instructions, or any combination thereof for performing a wet etching process to remove the nitride material from sidewalls of the stack to expose a sidewall of the nitride layer of at least one level of the set of levels that contacts the nitride material, where forming the cavity is based at least in part on performing the wet etching process.

Aspect 19: The method, apparatus, or non-transitory computer-readable medium of any of aspects 13 through 18, where each level of the set of levels includes a respective height and a respective width.

Aspect 20: The method, apparatus, or non-transitory computer-readable medium of any of aspects 13 through 19, further including operations, features, circuitry, logic, means, or instructions, or any combination thereof for depositing a second nitride material over the stack after depositing the nitride material over the stack, where forming the cavity further includes removing a portion of the second nitride material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 21: An apparatus, including: a stack of materials including a plurality of word lines, the plurality of word lines including a first word line and one or more second word lines; a rivet that couples the first word line of the plurality of word lines with a conductive pillar; the conductive pillar that couples the first word line with supporting circuitry, where a first thickness of the first thickness of the first word line adjacent to the conductive pillar is greater than a second thickness of the one or more second word lines adjacent to the conductive pillar; and a first oxide material isolating the conductive pillar from the one or more second word lines.

Aspect 22: The apparatus of aspect 21, further including: a plurality of second rivets each coupling a respective one of the one or more second word lines with a respective second conductive pillar of one or more second conductive pillars.

Aspect 23: The apparatus of aspect 22, where one or more portions of the first word line contact a second oxide material that isolates the first word line from the one or more second conductive pillars.

Aspect 24: The apparatus of any of aspects 21 through 23, where the conductive pillar traverses the stack of materials and is perpendicular to the first word line.

Aspect 25: The apparatus of any of aspects 21 through 24, where the stack of materials includes alternating layers of a word line of the plurality of word lines and an oxide layer of a plurality of oxide layers.

Aspect 26: The apparatus of any of aspects 21 through 25, where the supporting circuitry includes a metal oxide semiconductor that is positioned below the stack of materials.

Aspect 27: The apparatus of any of aspects 21 through 26, further including: a plurality of support vias electrically isolated from the plurality of word lines.

An apparatus is described. The following provides an overview of aspects of the apparatus as described herein:

Aspect 28: An apparatus, including: a stack of materials including a plurality of word lines, the plurality of word lines including a first word line and one or more second word lines; a plurality of rivets that each couple one word line of the plurality of word lines with one conductive pillar of a plurality of conductive pillars; the plurality of conductive pillars that each couple a respective one word line of the plurality of word lines with supporting circuitry, where a first thickness of each respective one word line adjacent to a corresponding conductive pillar is greater than a second thickness of the one word line adjacent to other conductive pillars of the plurality of conductive pillars; and a first oxide material isolating each word line of the plurality of word lines from the other conductive pillars of the plurality of conductive pillars.

Aspect 29: The apparatus of aspect 28, where each conductive pillars of the plurality of conductive pillars traverses the stack of materials and is perpendicular to each word line of the plurality of word lines.

Aspect 30: The apparatus of any of aspects 28 through 29, where the stack of materials includes alternating layers of a word line of the plurality of word lines and an oxide layer of a plurality of oxide layers.

Aspect 31: The apparatus of any of aspects 28 through 30, where the supporting circuitry includes a metal oxide semiconductor that is positioned below the stack of materials.

Aspect 32: The apparatus of any of aspects 28 through 31, further including: a plurality of support vias electrically isolated from the plurality of word lines.

An apparatus is described. The following provides an overview of aspects of the apparatus as described herein:

Aspect 33: An apparatus formed by a process including: forming a stack including a set of levels, each level of the set of levels including a nitride layer and an oxide layer; depositing a nitride material on the stack to contact at least a portion of the nitride layer of one or more levels of the set of levels; removing a portion of the stack to form a cavity including a first sidewall and a second sidewall; removing, based at least in part on forming the cavity, a portion of the nitride material and a portion of the nitride layer of each level of the set of levels to form a set of voids, where a first void of the set of voids is formed at a first level based at least in part on removing the portion of the nitride material and the portion of the nitride layer of the first level that is in contact with the portion of the nitride material, and where a second void of the set of voids is formed at a second level based at least in part on removing the portion of the nitride layer of the second level; conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void; and forming a rivet that couples a first word line with a conductive pillar based at least in part on conformally depositing the oxide layer, where the first word line is associated with the first level that includes the nitride material in contact with the portion of the nitride layer.

Aspect 34: The apparatus of aspect 33, where the process further includes: forming, after conformally depositing the oxide material, a plurality of word lines including at least the first word line and a second word line based at least in part on removing the nitride material and the nitride layer from each level of the set of levels to form a plurality of fourth voids and depositing a first conductive material in the plurality of fourth voids, where forming the rivet occurs after forming the plurality of word lines.

Aspect 35: The apparatus of aspect 34, where a first thickness of the first word line adjacent to the cavity is greater than a second thickness of the second word line adjacent to the cavity.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on.” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A. B. or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a stack comprising a set of levels, each level of the set of levels comprising a nitride layer and an oxide layer;
depositing a nitride material on the stack to contact at least a portion of the nitride layer of one or more levels of the set of levels;
removing a portion of the stack to form a cavity comprising a first sidewall and a second sidewall;
removing, based at least in part on forming the cavity, a portion of the nitride material and a portion of the nitride layer of each level of the set of levels to form a set of voids, wherein a first void of the set of voids is formed at a first level based at least in part on removing the portion of the nitride material and the portion of the nitride layer of the first level that is in contact with the portion of the nitride material, and wherein a second void of the set of voids is formed at a second level based at least in part on removing the portion of the nitride layer of the second level;
conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void; and
forming a rivet that couples a first word line with a conductive pillar based at least in part on conformally depositing the oxide material, wherein the first word line is associated with the first level that comprises the nitride material in contact with the portion of the nitride layer.

2. The method of claim 1, further comprising:
forming, after conformally depositing the oxide material, a plurality of word lines comprising at least the first word line and a second word line based at least in part on removing the nitride material and the nitride layer from each level of the set of levels to form a plurality of fourth voids and depositing a first conductive material in the plurality of fourth voids, wherein forming the rivet occurs after forming the plurality of word lines.

3. The method of claim 2, wherein a first thickness of the first word line adjacent to the cavity is greater than a second thickness of the second word line adjacent to the cavity.

4. The method of claim 2, further comprising:
removing, after forming the plurality of word lines, a portion of the oxide material from the first sidewall and the second sidewall of the cavity, wherein removing the portion of the oxide material from the third void exposes sidewalls of the first word line, and wherein removing the portion of the oxide material from the second void decreases a thickness of a remaining portion of the oxide material in the second void that contacts the second word line.

5. The method of claim 4, wherein removing the portion of the oxide material further comprises:
performing a wet etching process to conformally remove the portion of the oxide material from the first sidewall and the second sidewall of the cavity.

6. The method of claim 4, further comprising:
depositing, based at least in part on removing the portion of the oxide material, a second conductive material into the cavity to form the conductive pillar and the rivet, wherein the second conductive material contacts the first word line and is electrically isolated from the second word line by the remaining portion of the oxide material.

7. The method of claim 1, further comprising:
depositing a polysilicon material in the cavity after conformally depositing the oxide material, wherein forming the rivet occurs after depositing the polysilicon material in the cavity.

8. The method of claim 1, further comprising:
performing a wet etching process to remove the nitride material from sidewalls of the stack to expose a sidewall of the nitride layer of the one or more levels of the set of levels that contacts the nitride material, wherein forming the cavity is based at least in part on performing the wet etching process.

9. The method of claim 1, wherein forming the stack comprises:
depositing each nitride layer on each oxide layer to form the stack comprising a set of oxide layers interleaving a set of nitride layers.

10. The method of claim 9, further comprising:
removing a portion of the set of nitride layers and the set of oxide layers to form each level of the set of levels, wherein the portion comprises a first subset of the set of oxide layers and a first subset of the set of nitride layers, and wherein depositing the nitride material occurs after forming each level of the set of levels.

11. The method of claim 1, wherein each level of the set of levels comprises a respective height and a respective width.

12. The method of claim 1, further comprising:
depositing a second nitride material over the stack after depositing the nitride material over the stack, wherein forming the cavity further comprises removing a portion of the second nitride material.

13. An apparatus, comprising:
a stack of materials comprising a plurality of word lines, the plurality of word lines comprising a first word line and one or more second word lines;
a rivet that couples the first word line of the plurality of word lines with a conductive pillar;
the conductive pillar that couples the first word line with supporting circuitry, wherein a first thickness of the first thickness of the first word line adjacent to the conductive pillar is greater than a second thickness of the one or more second word lines adjacent to the conductive pillar; and
a first oxide material isolating the conductive pillar from the one or more second word lines.

14. The apparatus of claim 13, further comprising:
a plurality of second rivets each coupling a respective one of the one or more second word lines with a respective second conductive pillar of one or more second conductive pillars.

15. The apparatus of claim 14, wherein one or more portions of the first word line contact a second oxide material that isolates the first word line from the one or more second conductive pillars.

16. The apparatus of claim 13, wherein the conductive pillar traverses the stack of materials and is perpendicular to the first word line.

17. The apparatus of claim 13, wherein the stack of materials comprises alternating layers of a word line of the plurality of word lines and an oxide layer of a plurality of oxide layers.

18. The apparatus of claim 13, wherein the supporting circuitry comprises a metal oxide semiconductor that is positioned below the stack of materials.

19. The apparatus of claim 13, further comprising:
a plurality of support vias electrically isolated from the plurality of word lines.

20. An apparatus formed by a process comprising:
forming a stack comprising a set of levels, each level of the set of levels comprising a nitride layer and an oxide layer;
depositing a nitride material on the stack to contact at least a portion of the nitride layer of one or more levels of the set of levels;
removing a portion of the stack to form a cavity comprising a first sidewall and a second sidewall;
removing, based at least in part on forming the cavity, a portion of the nitride material and a portion of the nitride layer of each level of the set of levels to form a set of voids, wherein a first void of the set of voids is formed at a first level based at least in part on removing the portion of the nitride material and the portion of the nitride layer of the first level that is in contact with the portion of the nitride material, and wherein a second void of the set of voids is formed at a second level based at least in part on removing the portion of the nitride layer of the second level;
conformally depositing, based at least in part on removing the portion of the nitride material and the portion of the nitride layer of each level, an oxide material on the first sidewall and the second sidewall of the cavity, the oxide material filling a portion of the first void to form a third void that is smaller than the first void and filling the second void; and
forming a rivet that couples a first word line with a conductive pillar based at least in part on conformally depositing the oxide layer, wherein the first word line is associated with the first level that comprises the nitride material in contact with the portion of the nitride layer.
